(19) United States
(12) Patent Application Publication
(10) Pub. No.: US 2026/0123413 A1
(43) Pub. Date: Apr. 30, 2026

(54) TSV Interposer, Method for Manufacturing Therefor and Three-dimensional Chip

(71) Applicant: PEKING UNIVERSITY, Beijing (CN)

(72) Inventors: Zhenyu Wang, Beijing (CN); Shichuan Cao, Beijing (CN); Pengda Xiao, Beijing (CN); Tianjian Yu, Beijing (CN); Penghuai Shu, Beijing (CN); Yifei Gao, Beijing (CN); Yang Liu, Beijing (CN)

(21) Appl. No.: 18/566,913

(22) PCT Filed: Aug. 25, 2023
(86) PCT No.: PCT/CN2023/115066

§ 371 Date: Dec. 4, 2023

(30) Foreign Application Priority Data
Jul. 20, 2023 (CN) 202310900224.7

(51) Int. Cl. H10W 40/20; H10W 70/05; H10W 70/63

(52) U.S. Cl. CPC H10W 40/235; H10W 70/095; H10W 70/635

(57) ABSTRACT

The disclosure provides a through-silicon via (TSV) interposer, a method for manufacturing therefor and a three-dimensional chip. The TSV interposer includes: a substrate, and an interior of the substrate is provided with a cavity and a first structural layer covering a part of an inner wall of the cavity, and a material type of the first structural layer is different from a material type of the substrate; a via hole structure that penetrates the substrate and is located at a side of the cavity; and liquid metal located in the cavity, and the liquid metal and the first structural layer include a same material element.

### CROSS-REFERENCE TO RELATED APPLICATION

The disclosure is a U.S. national phase patent application of PCT/CN2023/115066 filed Aug. 25, 2023 which claims the benefit of and priority to Chinese Patent Application No. 202310900224.7, filed with the China National Intellectual Property Administration on Jul. 20, 2023 and entitled “TSV Interposer, Method for Manufacturing Therefor and Three-Dimensional Chip”, the entire contents of each of which is incorporated herein by reference.

### TECHNICAL FIELD

The disclosure relates to the technical field of semiconductors, in particular to a through-silicon via (TSV) interposer, a method for manufacturing therefor and a three-dimensional chip.

### BACKGROUND

In recent years, notable improvement in the integration of chips has been achieved along with in-depth research and rapid progress on integrated circuit package design, and extensive discussion and study into an integration technology of three-dimensional chips based on through-silicon vias (TSV) have also been made. Accordingly, higher technical standards and requirements have been put forward for the chip package technology. In some existing package technologies, large transmission signal losses will be generated when chips are stacked. After chips are stacked, generated heat increases while a corresponding heat dissipation area does not, resulting in a sharp increase in heating density. In addition, although multi-chip package can still maintain the original heat dissipation area, thermal coupling is strengthened due to corresponding connection of heat sources between different chips, which in turn causes more serious thermal problems. For radio frequency chips, C (4 GHz-8 GHZ) and Ku (12 GHz-18 GHz) are the most commonly used frequency bands for satellite services at present. Despite a larger available bandwidth, Ka band has higher requirements for devices and processes due to its more serious rain fading effects, and has been developing slowly. With continuous increase in computation power and power consumption of a central processing unit (CPU), it is urgent to efficiently dissipate heat. In practical application scenarios, requirements for the stress-strain situation, signal stability and radiation resistance of the chip under extreme working conditions are higher, and improvements in relevant loss reduction and heat dissipation technologies are required urgently.

### SUMMARY

A main objective of the disclosure is to provide a through-silicon via (TSV) interposer, a method for manufacturing therefor and a three-dimensional chip.

According to one aspect of the disclosure, a TSV interposer is provided. The TSV interposer includes: a substrate, and an interior of the substrate is provided with a cavity and a first structural layer covering a part of an inner wall of the cavity, and a material type of the first structural layer is different from a material type of the substrate; a via hole structure that penetrates the substrate and is located at a side of the cavity; and liquid metal located in the cavity, and the liquid metal and the first structural layer include a same material element.

In some embodiments, the TSV interposer further includes: a first trench that penetrates a part of a surface of the substrate and a part of a surface of the first structural layer and is in communication with the cavity; and a second structural layer located in the first trench.

In some embodiments, the substrate includes: a first sub-substrate; a second trench extending into the first sub-substrate from a surface of the first sub-substrate; a first structural sub-layer located at a bottom of the second trench; a second sub-substrate, and a surface of the second sub-substrate is bonded to the surface of the first sub-substrate; a third trench extending into the second sub-substrate from the surface of the second sub-substrate, and the second trench and the third trench corresponds to each other, so as to constitute the cavity; and a second structural sub-layer located at a bottom of the third trench, and the first structural sub-layer and the second structural sub-layer constitute the first structural layer.

In some embodiments, the via hole structure includes: a via hole that penetrates the substrate and is located at the side of the cavity; an insulation layer covering a hole wall of the via hole; a barrier layer located on a surface, far away from the hole wall of the via hole, of the insulation layer; and a conductive layer located on a surface, far away from the insulation layer, of the barrier layer.

In some embodiments, the TSV interposer further includes: a first metal connection structure located on a surface of the substrate, and the first metal connection structure is in contact with the via hole structure; and a second metal connection structure located on a surface, far away from the substrate, of the first metal connection structure.

In some embodiments, a material of the first structural layer includes a gallium-containing compound, and the liquid metal includes gallium.

In some embodiments, the liquid metal further includes at least one of silver, indium, tin, graphene, diamond nanoparticles and nitrogen boride.

According to another aspect of the disclosure, a method for manufacturing the TSV interposer is provided. The method includes: the substrate is provided, and the interior of the substrate is provided with the cavity and the first structural layer covering the part of the inner wall of the cavity, and the material type of the first structural layer is different from the material type of the substrate; the via hole structure that penetrates the substrate is formed at the side of the cavity; and the cavity is injected with liquid metal to obtain the TSV interposer, and the liquid metal and the first structural layer include the same material element.

In some embodiments, the cavity is injected with the liquid metal to obtain the TSV interposer includes: a first trench that sequentially penetrates the substrate and the first structural layer into the cavity is formed; the cavity is injected with the liquid metal through the first trench; and the first trench is filled with a second structural layer, and the second structural layer is cured.

In some embodiments, the cavity is injected with the liquid metal through the first trench includes: the substrate that is provided with the first trench is placed on a heating platform, and temperature of the heating platform is higher than or equal to a melting point of the liquid metal; the cavity is injected with the liquid metal through the first trench in a protective gas atmosphere; image information of the cavity is collected in an injection process of the liquid metal; and local temperature of the heating platform is adjusted in the injection process according to the image information, and partial bubbles are removed from the liquid metal.

In some embodiments, the heating platform is located in an injection chamber; the heating platform includes a plurality of heating arrays, and the injection chamber further includes an injection structure filled with the liquid metal, an image collection device and a light source; and the injection structure is located above the heating platform, the light source is located at a side of the heating platform, and the image collection device is located at a side of at least one of the following: a side, far away from the heating platform, of the injection structure, and a side, far away from the light source, of the heating platform; the cavity is injected with the liquid metal through the first trench in the protective gas atmosphere includes: nitrogen is introduced into the injection chamber, and the cavity is injected with the liquid metal through the first trench by opening the injection structure in a nitrogen atmosphere; the image information of the cavity is collected in the injection process of the liquid metal includes: the light source is turned on in the injection process of the liquid metal, the image information of the cavity is collected by the image collection device, the image information is transmitted to a display so that the display displays the image information; and the local temperature of the heating platform is adjusted in the injection process according to the image information includes: whether a bubble having a diameter greater than a preset diameter exists is determined according to the image information, and under the condition that the bubble having the diameter greater than the preset diameter exists, a heating temperature of the heating array corresponding to a position of the bubble is adjusted according to the position of the bubble.

In some embodiments, the substrate is provided includes: a first sub-substrate is provided, a part of the first sub-substrate is removed, and a second trench that extends into the first sub-substrate from a surface of the first sub-substrate is formed; a first structural sub-layer is formed at a bottom of the second trench; a second sub-substrate is provided, a part of the second sub-substrate is removed, and a third trench that extends into the second sub-substrate from a surface of the second sub-substrate is formed; a second structural sub-layer is formed at a bottom of the third trench, and the first structural sub-layer and the second structural sub-layer constitute the first structural layer; and the first sub-substrate that is provided with the first structural sub-layer is bonded to the second sub-substrate that is provided with the second structural sub-layer by taking the surface of the first sub-substrate and the surface of the second sub-substrate as bonding interfaces, and the substrate is obtained, and the second trench and the third trench constitute the cavity.

In some embodiments, the via hole structure that penetrates the substrate is formed at the side of the cavity includes: a part of the substrate is removed, and a fourth initial trench that extends into the substrate from a first surface of the substrate is formed; an insulation layer, a barrier layer and a conductive layer are sequentially formed on a side wall of the fourth initial trench, and a fourth trench is obtained; and the substrate is polished along a second surface of the substrate until the fourth trench is cut through so as to obtain the via hole structure, and the first surface and the second surface are two opposite surfaces of the substrate.

In some embodiments, after the via hole structure is obtained, the method further includes: redistributing is performed on the first surface and the second surface to obtain a first metal connection structure in contact with the via hole structure; and a second metal connection structure is formed on a surface, far away from the substrate, of the first metal connection structure.

According to yet another aspect of the disclosure, a three-dimensional chip is provided. The three-dimensional chip includes: any TSV interposer described above, or a TSV interposer obtained by any of the method for manufacturing the TSV interposer described above.

### BRIEF DESCRIPTION OF THE DRAWINGS

The companying drawings of the description are used for further understanding of the disclosure as a constituent part of the description. Exemplary embodiments of the disclosure and their specification are used for explaining the disclosure, and do not constitute improper limitation to the disclosure. In the accompanying drawings:

FIG. 1 shows a schematic structural diagram of a through-silicon via (TSV) interposer according to an embodiment of the disclosure;

FIG. 2 shows a schematic flowchart of a method for manufacturing a TSV interposer according to an embodiment of the disclosure;

FIGS. 3-11 show schematic diagrams of structures obtained after process steps of a method for manufacturing a TSV interposer according to an embodiment of the disclosure;

FIG. 12 shows a schematic structural diagram of an injection chamber according to an embodiment of the disclosure;

FIG. 13 shows a schematic structural diagram of another TSV interposer according to an embodiment of the disclosure;

FIG. 14 shows an exploded diagram of a TSV interposer of a single-band radio frequency transmitter/receiver (T/R) sub-array according to an embodiment of the disclosure;

FIG. 15(a) shows a schematic structural diagram of parallel TSV arrays of a single central processing unit (CPU) computation unit according to an embodiment of the disclosure;

FIG. 15(b) shows a comparison diagram of TSV inter-column signal losses in terms of water, silicon and gallium of a single CPU computation unit according to an embodiment of the disclosure;

FIG. 15(c) shows a schematic structural diagram of a coaxial TSV array of a single-band radio frequency T/R sub-array according to an embodiment of the disclosure;

FIG. 15(d) shows a comparison diagram of TSV inter-column signal losses in terms of water, silicon and gallium of a single-band radio frequency T/R sub-array according to an embodiment of the disclosure;

FIG. 16(a) shows a simulation diagram of accumulated stresses under working conditions of a TSV interposer of a single CPU computation unit according to an embodiment of the disclosure;

FIG. 16(b) shows a simulation diagram of accumulated stresses under working conditions of a TSV interposer of a single-band radio frequency T/R sub-array according to an embodiment of the disclosure;

FIG. 17(a) shows a single particle simulation diagram of a 200 μm silicon substrate/embedded 100 μm gallium silicon substrate/100 μm gallium-based alloy silicon substrate/3.8 mm molybdenum-copper cover plate under irradiation of 6 MeV protons according to an embodiment of the disclosure;

FIG. 17(b) shows a total dose simulation diagram of a 200 μm silicon substrate/embedded 100 μm gallium silicon substrate/100 μm gallium-based alloy silicon substrate/3.8 mm molybdenum-copper cover plate under irradiation of one hundred of 6 MeV gamma particles according to an embodiment of the disclosure;

FIG. 18(a) shows a three-dimensional temperature distribution diagram of a local area of a liquid metal-embedded TSV interposer of a single CPU according to an embodiment of the disclosure; and

FIG. 18(b) shows a three-dimensional temperature distribution diagram of a local area of a TSV interposer of a single-band radio frequency T/R sub-array according to an embodiment of the disclosure.

The accompanying drawings include the following reference numerals:

10. substrate; 11. cavity; 12. first structural layer; 13. via hole structure; 14. liquid metal; 15. first trench; 16. second structural layer; 17. first sub-substrate; 18. second trench; 19. first structural sub-layer; 20. second sub-substrate; 21. third trench; 22. second structural sub-layer; 23. via hole; 24. insulation layer; 25. barrier layer; 26. conductive layer; 27. first metal connection structure; 28. initial substrate; 29. fourth trench; 30. heating platform; 31. injection chamber; 32. injection structure; 33. image collection device; 34. light source; 35. glove port; 36. gas inlet and outlet ball valve; and 37. second metal connection structure.

### DETAILED DESCRIPTION OF THE EMBODIMENTS

It should be noted that embodiments in the disclosure and features in the embodiments can be combined mutually if there is no conflict. The disclosure will be described in detail below with reference to accompanying drawings and in conjunction with the embodiments.

In order to enable a person of ordinary skill in the art to better understand solutions of the disclosure, technical solutions in the embodiments of the disclosure will be clearly and completely described below with reference to the accompanying drawings in the embodiments of the disclosure. Apparently, the described embodiments are merely some embodiments rather than all embodiments of the disclosure. All other embodiments derived by a person of ordinary skill in the art from the embodiments of the disclosure without creative efforts shall fall within the protection scope of the disclosure.

It should be noted that the terms “first”, “second”, etc. in the description, claims and the accompanying drawings of the disclosure are used to distinguish similar objects, but are not necessarily used to describe a specific sequence or a precedence order. It should be understood that the data used in this way can be interchanged under appropriate circumstances for the purposes of the embodiments of the disclosure described herein. In addition, terms “comprise”, “include”, “provided with” and “have”, and their variations are intended to cover non-exclusive inclusions, for example, processes, methods, systems, products, or devices that include a series of steps or units are not necessarily limited to those clearly listed steps or units, but can include other steps or units not explicitly listed or inherent to these processes, methods, products, or devices.

As introduced in the background, a heat dissipation capacity of a through-silicon via (TSV) interposer in the prior art is poor. In order to solve the above technical problem, the embodiments of the disclosure provide a TSV interposer, a method for manufacturing therefor and a three-dimensional chip.

The technical solutions in the embodiments of the disclosure will be described clearly and comprehensively below in conjunction with the accompanying drawings in the embodiments of the disclosure.

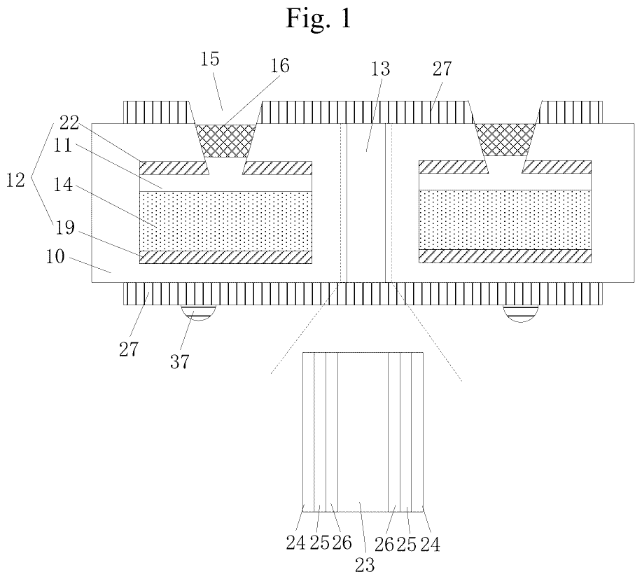

According to one aspect of the disclosure, a TSV interposer is provided. As shown in FIG. 1, the TSV interposer includes:
a substrate 10, and an interior of the substrate 10 is provided with a cavity 11 and a first structural layer 12 covering a part of an inner wall of the cavity 11, and a material type of the first structural layer 12 is different from a material type of the substrate 10;
a via hole structure 13 that penetrates the substrate 10 and is located at a side of the cavity 11; and
liquid metal 14 located in the cavity 11, and the liquid metal and the first structural layer include a same material element.

In the TSV interposer, the via hole structure penetrates the substrate, the cavity is located inside the substrate and at a side of the via hole structure, the first structural layer covers the part of the inner wall of the cavity, and the liquid metal is located in the cavity. According to the disclosure, the liquid metal is formed in the cavity inside the TSV interposer, such that heat dissipation performance of the TSV interposer can be improved by a high thermal conductivity of the liquid metal, and the problem of poor heat dissipation capacity of the TSV interposer in the prior art is alleviated. Moreover, a fully connected cavity of the via hole structure which is located at the side of the cavity naturally forms a kind of planar heat pipe micro-needle fin wick structure, and provides a favorable space environment for adaptive thermal reflux of the liquid metal. In addition, the material types of the first structural layer and the substrate are different, and the first structural layer and the liquid metal have the same material element. In this way, the first structural layer plays a heterogeneous transition role between the substrate and the liquid metal, the liquid metal has desirable fluidity in the cavity, and an overall cooling effect on the TSV interposer is further guaranteed to be desirable.

Specifically, the liquid metal may be any suitable low-melting-point amorphous metal material, such as gallium, rubidium and cesium, or an alloy including the metal material. The first structural layer is a metal compound including this metal material. Those skilled in the art can flexibly set materials of the liquid metal and the first structural layer according to actual needs.

In an optional embodiment, a material of the first structural layer includes a gallium-containing compound, and the liquid metal includes gallium. Gallium-based liquid metal has excellent features such as desirable fluidity, a low loss and a high thermal conductivity, such that the heat dissipation performance of the TSV interposer can be further improved, and overall structural strength and signal transmission stability of TSV interposer can be further enhanced.

In an actual application process, the substrate may be selected according to actual needs of the device, and may include a silicon substrate, a germanium substrate, a silicon germanium substrate, a silicon on insulator (SOI) substrate or a germanium on insulator (GOI) substrate. In other embodiments, the substrate may further be a substrate including other element semiconductors or compound semiconductors, such as GaAs, InP or SiC, and may also be a stacked structure, such as Si/SiGe, and other epitaxial structures, such as silicon germanium on insulator (SGOI). It is certain that the substrate may also be other substrates that are feasible in the prior art.

Further, the substrate is the silicon substrate, the first structural layer is a gallium nitride layer or a gallium arsenide layer, and the liquid metal is liquid gallium. The liquid gallium has excellent temperature uniformity performance, and a thermal metal slip speed of the liquid gallium can be enhanced through the gallium nitride layer or gallium arsenide layer, and a radial passive heat dissipation capacity of the TSV interposer can be enhanced without affecting a relevant standard process of the TSV interposer.

Specifically, as shown in FIG. 1, the TSV interposer further includes: a first trench 15 that penetrates a part of a surface of the substrate 10 and a part of a surface of the first structural layer 12 and is in communication with the cavity 11; and a second structural layer 16 located in the first trench 15. The first trench is in communication with the cavity, such that the cavity is injected with the liquid metal, and the cavity injected with the liquid metal is blocked through the second structural layer.

More specifically, the second structural layer may be a high-temperature ceramic adhesive. Solid connection to the substrate can be implemented through the high-temperature ceramic adhesive, such that the liquid metal can be further blocked in the cavity tightly.

In order to further solve the problem of the poor heat dissipation effect of the TSV interposer and further improve a structural strength of the TSV interposer, according to another exemplary embodiment, the substrate includes: a first sub-substrate; a second trench extending into the first sub-substrate from a surface of the first sub-substrate; a first structural sub-layer located at a bottom of the second trench; a second sub-substrate, and a surface of the second sub-substrate is bonded to the surface of the first sub-substrate; a third trench extending into the second sub-substrate from the surface of the second sub-substrate, and the second trench and the third trench corresponds to each other, so as to constitute the cavity; and a second structural sub-layer located at a bottom of the third trench, and the first structural sub-layer and the second structural sub-layer constitute the first structural layer. In this embodiment, the first sub-substrate that is provided with the second trench is bonded to the second sub-substrate that is provided with the third trench, to obtain the substrate that is internally provided with the cavity, such that it is guaranteed that the obtained substrate has uniform thermal distribution, desirable seismic performance and high connection strength, it is further guaranteed that the TSV interposer has strong compressive stress, and the TSV interposer can withstand a harsh working environment and has high process compatibility. Moreover, the first structural sub-layer and the second structural sub-layer cover the bottom of the second trench and the bottom of the third trench respectively, such that it is further guaranteed that the liquid metal has desirable flowing performance and high thermal slip speeds on the first structural sub-layer and the second structural sub-layer, the liquid metal has a better temperature uniformity effect and the heat dissipation capacity of the overall TSV is further improved.

Optionally, as shown in FIG. 1, the via hole structure 13 includes: a via hole 23 that penetrates the substrate 10 and is located at the side of the cavity 11; an insulation layer 24 covering a hole wall of the via hole 23; a barrier layer 25 located on a surface, far away from the hole wall of the via hole 23, of the insulation layer 24; and a conductive layer 26 located on a surface, far away from the insulation layer 24, of the barrier layer 25. Due to the conductivity of the substrate, it is necessary to form the insulation layer between the substrate and the conductive layer. In order to prevent the condition that conductive particles in the conductive layer diffuse into the insulation layer and affect electrical features of the insulation layer, the barrier layer is arranged between the insulation layer and the conductive layer for preventing diffusion of the conductive particles and improving adhesion strength of the conductive layer.

In an actual application process, a material of the insulation layer is generally selected as silicon oxide for isolating signals since the silicon oxide is convenient to manufacture in the silicon via and compatible with an IC process. A material of the barrier layer may be selected as polysilicon, and a material of the conductive layer may be selected as a metal material, such as copper columns, for transmitting signals. It is certain that the materials of the insulation layer, the barrier layer and the conductive layer are not limited to the materials, and those skilled in the art can choose any suitable materials as the insulation layer, the barrier layer and the conductive layer. The insulation layer, the barrier layer and the conductive layer are not limited to single-layer structures, but may also be multi-layer composite layer structures.

It should be noted that the via hole covering the insulation layer, the barrier layer and the conductive layer still has a cut through hole.

In some exemplary embodiments, as shown in FIG. 1, the TSV interposer further includes: a first metal connection structure 27 located on a surface of the substrate 10, and the first metal connection structure 27 is in contact with the via hole structure 13; and a second metal connection structure 37 located on a surface, far away from the substrate 10, of the first metal connection structure 27. Through the first metal connection structure and the second metal connection structure, requirements of the TSV interposer for subsequent connection and package are satisfied.

In an actual application process, those skilled in the art can select any suitable metal material as a material of the first metal connection structure and a material of the second metal connection structure. The material of the first metal connection structure and the material of the second metal connection structure may be the same or not, and are not specifically limited in the disclosure. In an optional embodiment, the material of the first metal connection structure is copper, and the material of the second metal connection structure is aurum.

According to some other embodiments, a plurality of via hole structures are provided. The plurality of the via hole structures may be evenly spaced or not. The plurality of the via hole structures may be arranged at the same side of the cavity or at two sides of the cavity. The plurality of arranged via hole structures and a fully connected cavity naturally form a kind of planar heat pipe micro-needle fin array wick structure, and create a favorable space environment for adaptive thermal reflux of the gallium-based liquid metal. In this way, the radial passive heat dissipation capacity of the TSV interposer can be further enhanced without affecting existing functions of the TSV interposer.

In order to further improve the heat dissipation capacity of the overall TSV interposer, in other embodiments, a plurality of cavities may be provided, and the plurality of the cavities are distributed in the substrate at intervals.

In the disclosure, the liquid metal further includes at least one of silver, indium, tin, graphene, diamond nanoparticles and nitrogen boride besides gallium. Under the condition that the liquid metal further includes at least one of indium and silver, at least one of indium and silver can improve cooling performance and an electromagnetic shielding capacity of the overall TSV interposer. Under the condition that the liquid metal further includes lead, radiation resistance of the overall TSV interposer can be further improved through uniform distribution of large-mass atoms such as lead in the cavity.

It is certain that the liquid metal is not limited to the above materials, and may further include other components that can enhance the heat dissipation capacity. In addition, under the condition that the liquid metal includes lead, a mass fraction of the lead may be 5%.

A method for manufacturing the TSV interposer is provided in this embodiment. Although a logical sequence is shown in the flowchart, in some cases, the steps shown or described may be executed in a sequence different from that stated herein.

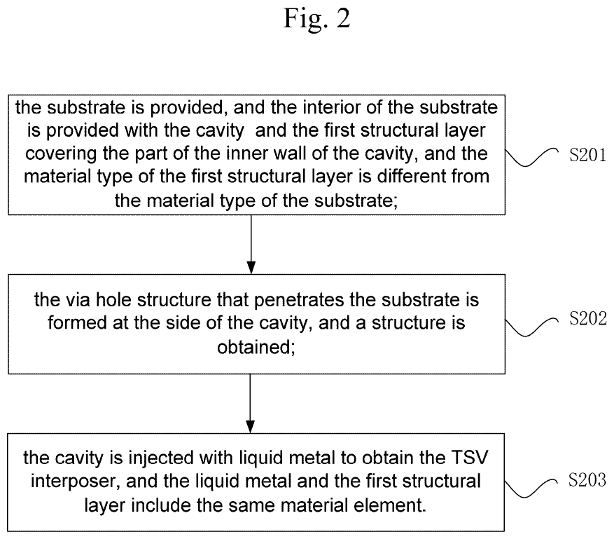

FIG. 2 shows a flowchart of a method for manufacturing the TSV interposer according to an embodiment of the disclosure. As shown in FIG. 2, the method includes:

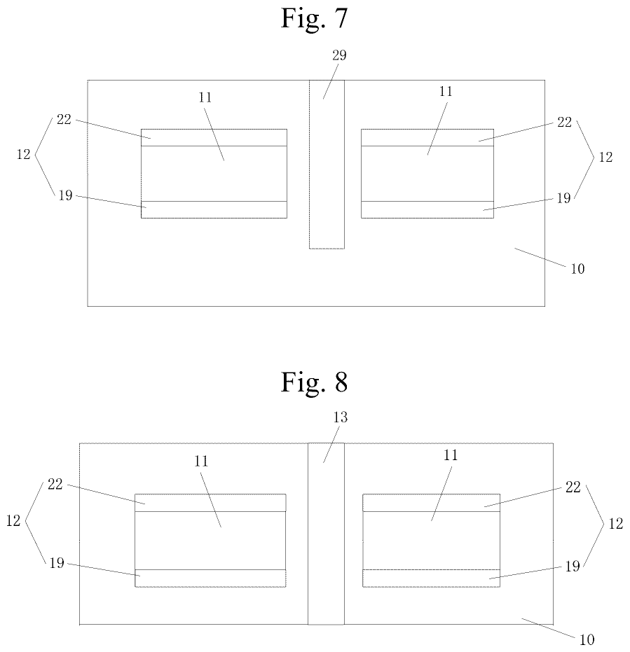

S201, the substrate 10 is provided as shown in FIG. 6, and the interior of the substrate 10 is provided with the cavity 11 and the first structural layer 12 covering the part of the inner wall of the cavity 11, and the material type of the first structural layer 12 is different from the material type of the substrate 10;

Specifically, the substrate may be selected according to actual needs of the device, and may include a silicon substrate, a germanium substrate, a silicon germanium substrate, an SOI substrate or a GOI substrate. In other embodiments, the substrate may further be a substrate including other element semiconductors or compound semiconductors, such as GaAs, InP or SiC, and may also be a stacked structure, such as Si/SiGe, and other epitaxial structures, such as SGOI. It is certain that the substrate may also be other substrates that are feasible in the prior art.

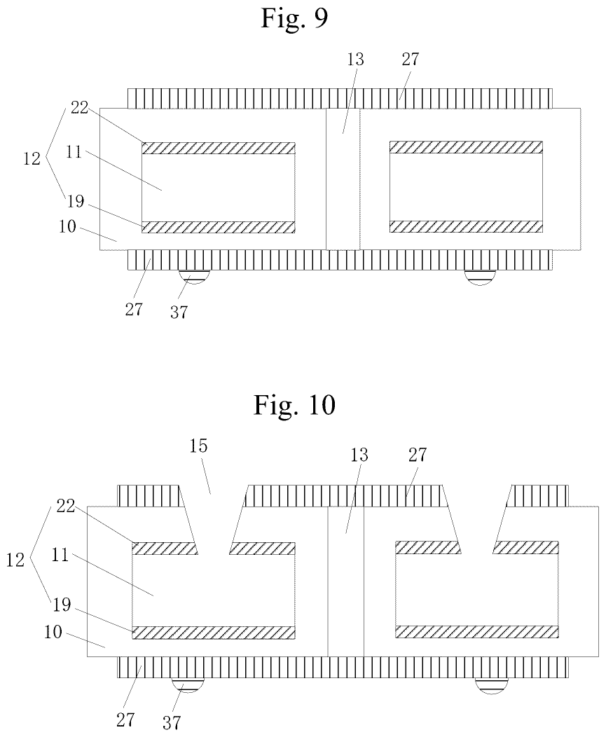

S202, the via hole structure 13 that penetrates the substrate is formed at the side of the cavity 11, and a structure is obtained as shown in FIG. 7;

S203, the cavity 11 is injected with liquid metal 14 to obtain the TSV interposer as shown in FIG. 1, and the liquid metal and the first structural layer include the same material element. Specifically, the liquid metal may be any suitable low-melting-point amorphous metal

material, such as gallium, rubidium and cesium, or an alloy including the metal material. The first structural layer is a metal compound including this metal material. Those skilled in the art can flexibly set materials of the liquid metal and the first structural layer according to actual needs.

Through the above embodiment, firstly, the substrate is provided, and the interior of the substrate is provided with the cavity and the first structural layer covering the part of the inner wall of the cavity. Then, the via hole structure that penetrates the substrate is formed at the side of the cavity. Finally, the TSV interposer is obtained by injecting the cavity with the liquid metal. According to the disclosure, the liquid metal is formed in the cavity inside the TSV interposer, such that heat dissipation performance of the TSV interposer can be improved by a high thermal conductivity of the liquid metal, and the problem of poor heat dissipation capacity of the TSV interposer in the prior art is alleviated. Moreover, a fully connected cavity of the via hole structure which is located at the side of the cavity naturally forms a kind of planar heat pipe micro-needle fin wick structure, and provides a favorable space environment for adaptive thermal reflux of the liquid metal. In addition, the material types of the first structural layer and the substrate are different, and the first structural layer and the liquid metal have the same material element. In this way, the first structural layer plays a heterogeneous transition role between the substrate and the liquid metal, the liquid metal has desirable fluidity in the cavity, and an overall cooling effect on the TSV interposer is further guaranteed to be desirable.

Specifically, a material of the first structural layer includes a gallium-containing compound, and the liquid metal includes gallium. Gallium-based liquid metal has excellent features such as desirable fluidity, a low loss and a high thermal conductivity, such that the heat dissipation performance of the TSV interposer can be further improved, and overall structural strength and signal transmission stability of TSV interposer can be further enhanced.

Further, the substrate is the silicon substrate, the first structural layer is a gallium nitride layer or a gallium arsenide layer, and the liquid metal is liquid gallium. The liquid gallium has excellent temperature uniformity performance, and a thermal metal slip speed of the liquid gallium can be enhanced through the gallium nitride layer or gallium arsenide layer, and a radial passive heat dissipation capacity of the TSV interposer can be enhanced without affecting a relevant standard process of the TSV interposer.

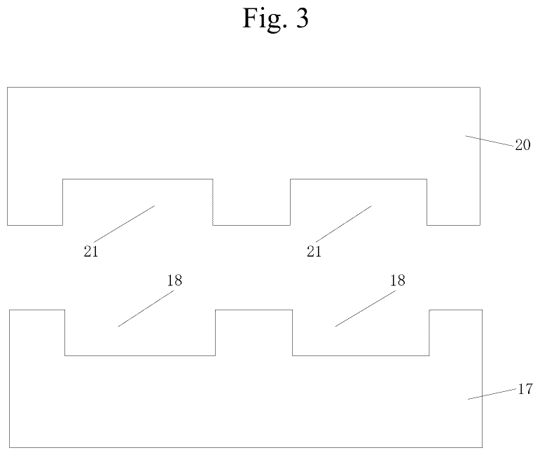

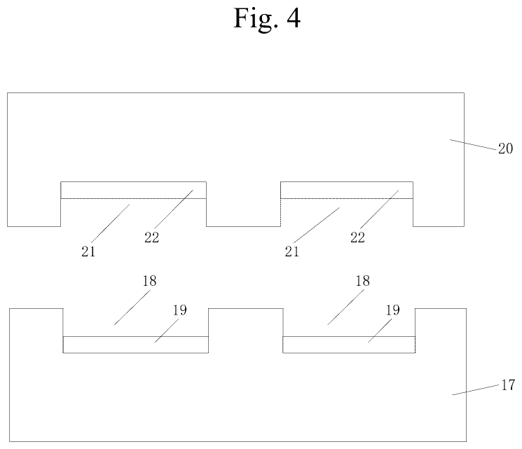

According to another specific embodiment of the disclosure, the substrate is provided includes: a first sub-substrate 17 is provided, a part of the first sub-substrate 17 is removed, as shown in FIG. 3, and a second trench 18 that extends into the first sub-substrate 17 from a surface of the first sub-substrate 17 is formed; as shown in FIG. 4, a first structural sub-layer 19 is formed at a bottom of the second trench 18; a second sub-substrate 20 is provided, a part of the second sub-substrate 20 is removed, and as shown in FIG. 3, a third trench 21 that extends into the second sub-substrate 20 from a surface of the second sub-substrate 20 is formed; as shown in FIG. 4, a second structural sub-layer 22 is formed at a bottom of the third trench 21, and the first structural sub-layer 19 and the second structural sub-layer 22 constitute the first structural layer 12; the first sub-substrate 17 that is provided with the first structural sub-layer 19 is bonded to the second sub-substrate 20 that is provided with the second structural sub-layer 22 by taking the surface of the first sub-substrate 17 and the surface of the second sub-substrate 20 as bonding interfaces, and the substrate 10 is obtained as shown in FIG. 6, and the second trench 18 and the third trench 21 in FIG. 4 constitute the cavity 11 in FIG. 6. In this embodiment, the first sub-substrate that is provided with the second trench is bonded to the second sub-substrate that is provided with the third trench, and the substrate that is internally provided with the cavity is obtained, such that it is guaranteed that the obtained substrate has uniform thermal distribution, desirable seismic performance and high connection strength, it is further guaranteed that the TSV interposer has strong compressive stress, and the TSV interposer can withstand a harsh working environment and has high process compatibility. Moreover, the first structural sub-layer and the second structural sub-layer cover the bottom of the second trench and the bottom of the third trench respectively, such that it is further guaranteed that the liquid metal has desirable flowing performance and high thermal slip speeds on the first structural sub-layer and the second structural sub-layer, the liquid metal has a better temperature uniformity effect and the heat dissipation capacity of the overall TSV is further improved.

The part of the first sub-substrate is removed, and the second trench that extends into the first sub-substrate from the surface of the first sub-substrate is formed includes: deep reactive ion etching is performed on the first sub-substrate by an ion etching machine to form the second trench. The part of the second sub-substrate is removed, and the third trench that extends into the second sub-substrate from the surface of the second sub-substrate is formed includes: deep reactive ion etching is performed on the second sub-substrate by an ion etching machine to form the third trench.

The first structural sub-layer is formed at the bottom of the second trench includes: a first prepared structural layer is formed on an exposed surface, provided with the second trench, of the first sub-substrate by a metalorganic vapor phase epitaxy process; the formed first prepared structural layer is etched with a wet etcher, and the first prepared structural layer located at the bottom of the second trench is merely retained to obtain the first structural sub-layer. The second structural sub-layer is formed at the bottom of the third trench includes: a second prepared structural layer is formed on an exposed surface, provided with the third trench, of the second sub-substrate by a metalorganic vapor phase epitaxy process; the formed second prepared structural layer is etched with a wet etcher, and the second prepared structural layer located at the bottom of the third trench is merely retained to obtain the second structural sub-layer.

In a process of generating the first prepared structural layer and the second prepared structural layer by adopting the metalorganic vapor phase epitaxy process, a silicon wafer is put into a reaction cavity, and trimethyl gallium and ammonia gas NH₃ are simultaneously introduced into the reaction cavity for reaction, and a chemical reaction formula is as follows:

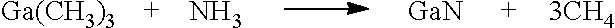

Since a tensile stress of GaN on a silicon surface is large, a crack, roughness, etc. are likely to occur on GaN on the silicon substrate. In order to epitaxially grow high-quality GaN, a layer of HT-AlN with desirable thermal stability may be added to epitaxy of the silicon substrate as a buffer layer, and the tensile stress of GaN is converted into a compressive stress, such that growth quality of a GaN epitaxial layer may be greatly improved. However, in order to increase a surface tension difference, it is necessary to increase roughness of a GaN—Si heterogeneous interface, so quality requirements for GaN in a fabrication process of the disclosure are much lower than those for epitaxial GaN as a semiconductor device substrate. As a result, a 100 nm GaN epitaxial layer may be directly grown on the silicon substrate, and a nanostructure heterogeneous interface that satisfies the requirements of certain roughness range is obtained.

A specific process of etching the first prepared structural layer and the second prepared structural layer with the wet etcher may be as follows: the first sub-substrate that is provided with the first prepared structural layer and the second sub-substrate that is provided with the second prepared structural layer are soaked in a potassium hydroxide (KOH) solution, the epitaxial gallium nitride layer with a thickness of 100 nm is etched through an electrochemical reaction, and a required graphical heterogeneous interface is formed.

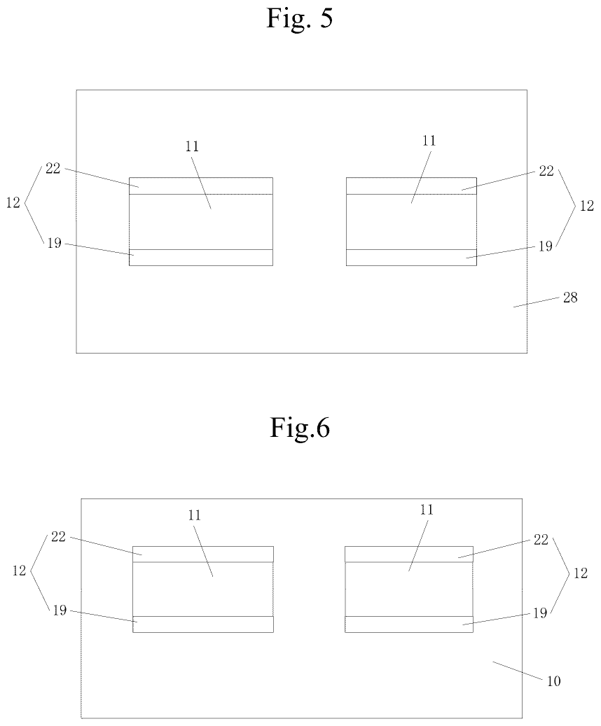

In addition, the first sub-substrate 17 that is provided with the first structural sub-layer 19 is bonded to the second sub-substrate 20 that is provided with the second structural sub-layer 22 by taking the surface of the first sub-substrate 17 and the surface of the second sub-substrate 20 as the bonding interfaces, the substrate 10 is obtained as shown in FIG. 6, and the second trench 18 and the third trench 21 constitute the cavity includes: the first sub-substrate 17 that is provided with the first structural sub-layer 19 is bonded to the second sub-substrate 20 that is provided with the second structural sub-layer 22 by taking the surface of the first sub-substrate 17 and the surface of the second sub-substrate 20 as the bonding interfaces, so as to obtain an initial substrate 28 as shown in FIG. 5; a surface of the initial substrate is subjected to chemical mechanical polishing, and a thickness of the polished initial substrate reaches a preset thickness, such as 60 μm. It is certain that the thickness of the substrate is not limited to the 60 μm, and this value may be determined according to an actual process.

In an actual application, a depth of the cavity covered with the first structural layer may be 100 μm or any other suitable numerical value.

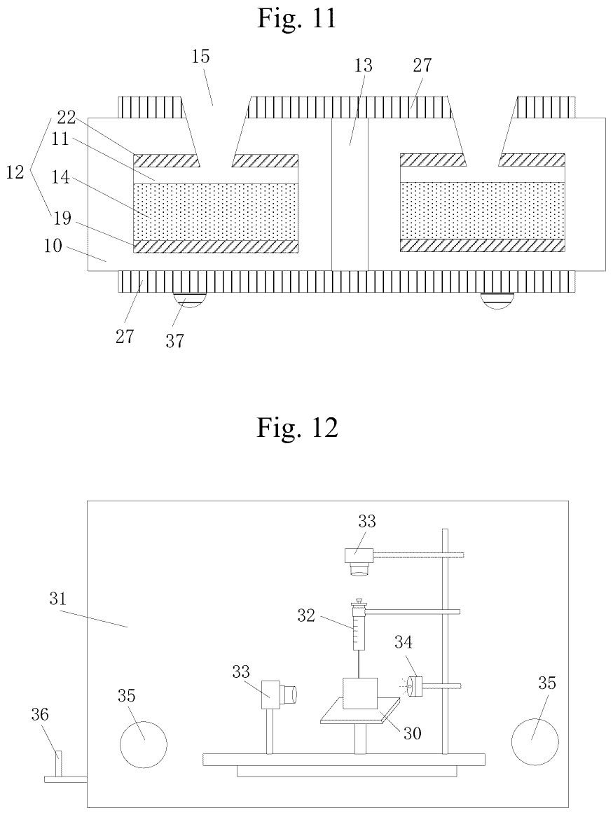

Optionally, the via hole structure that penetrates the substrate is formed at the side of the cavity includes: a part of the substrate is removed, and a fourth initial trench that extends into the substrate from a first surface of the substrate is formed; an insulation layer, a barrier layer and a conductive layer are sequentially formed on a side wall of the fourth initial trench, and a fourth trench 29 is obtained as shown in FIG. 7; the substrate 10 is polished along a second surface of the substrate 10 until the fourth trench 29 is cut through, so as to obtain the via hole structure 13 as shown in FIG. 8, and the first surface and the second surface are two opposite surfaces of the substrate 10.

Specifically, a thickness of the substrate that is provided with the via hole structure may be 150 μm. Those skilled in the art may flexibly set the thickness of a ground substrate according to actual process requirements.

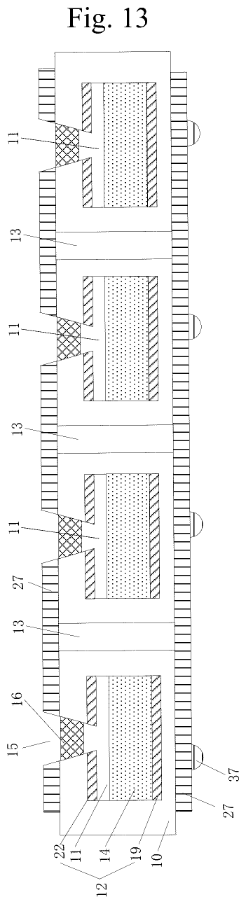

According to another optional embodiment of the disclosure, after the via hole structure is obtained, the method further includes: as shown in FIGS. 8 and 9, redistributing is performed on the first surface and the second surface to obtain a first metal connection structure 27 in contact with the via hole structure 13; a second metal connection structure 37 is formed on a surface, far away from the substrate 10, of the first metal connection structure 27. Through the first metal connection structure and the second metal connection structure, requirements of the TSV interposer for subsequent connection and package are satisfied.

In an actual application process, those skilled in the art can select any suitable metal material as a material of the first metal connection structure and a material of the second metal connection structure. The material of the first metal connection structure and the material of the second metal connection structure may be the same or not, and are not specifically limited in the disclosure. In an optional embodiment, the material of the first metal connection structure is copper, and the material of the second metal connection structure is aurum.

Further, a magnetron sputtering machine may be used to perform redistributing on the first surface and the second surface.

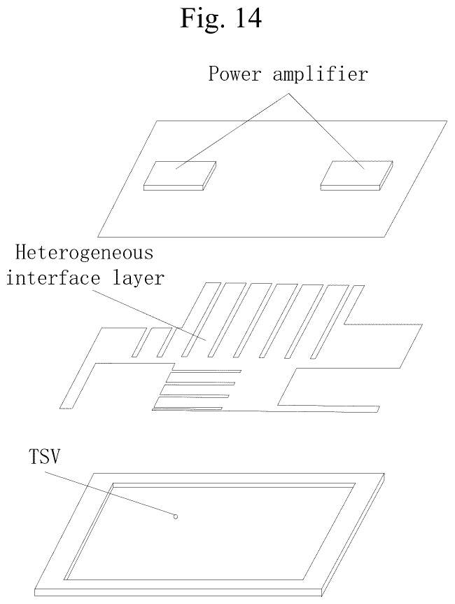

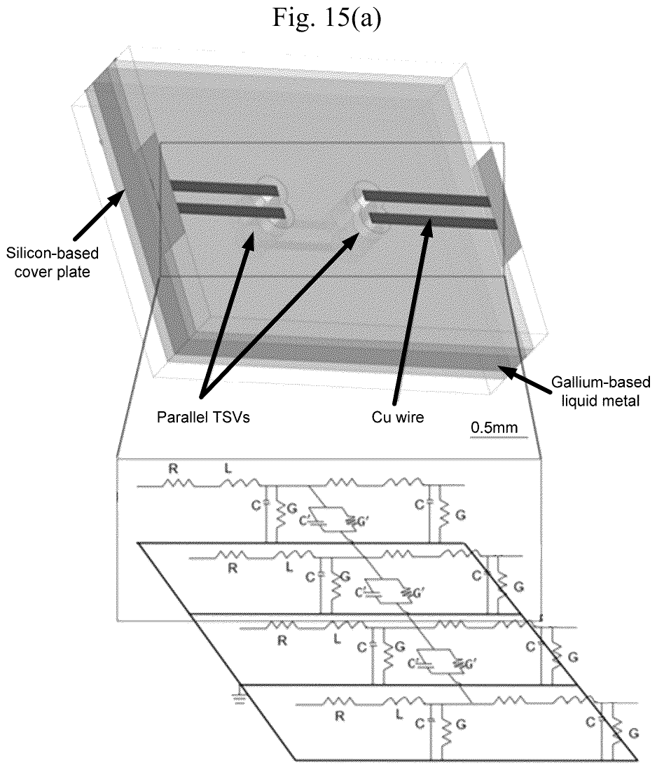

In a still optional embodiment, the cavity is injected with the metal to obtain the TSV interposer includes: as shown in FIG. 10, a first trench 15 that sequentially penetrates the substrate 10 and the first structural layer 12 into the cavity 11 is formed; as shown in FIG. 11, the cavity 11 is injected with the liquid metal 14 through the first trench 15; as shown in FIG. 1, the first trench 15 is filled with a second structural layer 16, and the second structural layer 16 is cured. The first trench in communication with the cavity is formed, such that the cavity is injected with the liquid metal, and the cavity injected with the liquid metal is blocked through the second structural layer.

Specifically, the second structural layer is cured includes: a structure provided with the second structural layer is put into a high-temperature oven, temperature of the high-temperature oven is set to a preset temperature, and the second structural layer is cured. The first trench that sequentially penetrates the substrate and the first structural layer into the cavity is formed includes: deep reactive ion etching is performed on the substrate by an ion etching machine, and the first trench is obtained.

In a specific application, those skilled in the art may set the preset temperature according to the material of the second structural layer. For example, under the condition that the second structural layer is a high-temperature ceramic adhesive, the preset temperature may be 200° C. At the temperature, the ceramic adhesive can be completely cured, and stable connection and packaging effects are guaranteed.

The process step that the first metal connection structure is formed may be performed after the cavity is injected with the liquid metal, or after the via hole structure is obtained and before the cavity is injected with the liquid metal. The step that under the condition that the first metal connection structure is formed before the cavity is injected with the liquid metal, the first trench 15 that sequentially penetrates the substrate 10 and the first structural layer 12 into the cavity 11 is formed includes: as shown in FIGS. 9 and 10, with an ion etching machine, a part of the first metal connection structure 27, a part of the substrate 10 and a part of the first structural layer 12 are sequentially etched and removed through a deep reactive ion etching process to form the first trench 15.

In the embodiment of the disclosure, the cavity is injected with the liquid metal through the first trench includes: the substrate that is provided with the first trench is placed on a heating platform, and temperature of the heating platform is higher than or equal to a melting point of the liquid metal; the cavity is injected with the liquid metal through the first trench in a protective gas atmosphere; image information of the cavity is collected in an injection process of the liquid metal; local temperature of the heating platform is adjusted in the injection process according to the image information, and partial bubbles are removed from the liquid metal. In this embodiment, the cavity is injected with the liquid metal in a protective gas atmosphere, such that oxidation and denaturation of the liquid metal caused by contact between the liquid metal with air are avoided. In addition, the image information of the cavity is collected in an injection process of the liquid metal, and the local temperature of the heating platform of the heated cavity is adjusted according to the image information, such that impaction of protective gas bubbles during the injection process is avoided, and injection quality is guaranteed to be high.

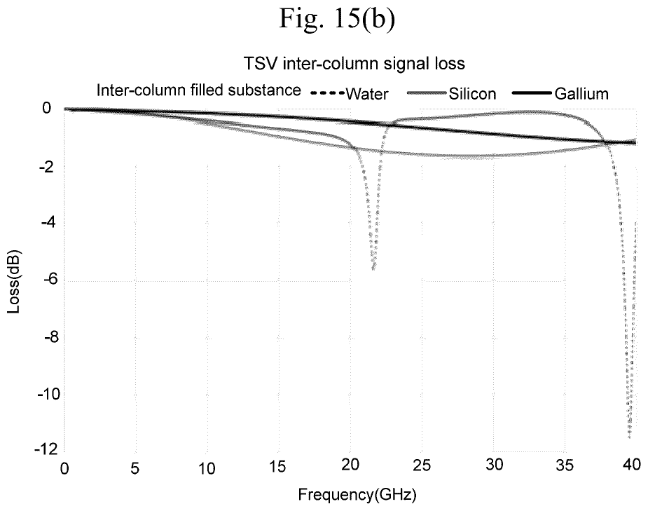

Specifically, as shown in FIG. 12, the heating platform 30 is located in an injection chamber 31. The heating platform 30 includes a plurality of heating arrays, and the injection chamber 31 further includes an injection structure 32 filled with the liquid metal, an image collection device 33 and a light source 34. The injection structure 32 is located above the heating platform 30, the light source 34 is located at a side of the heating platform 30, and the image collection device 33 is located at a side of at least one of the following: a side, far away from the heating platform 30, of the injection structure 32, and a side, far away from the light source 34, of the heating platform 30.

Based on this, the cavity is injected with the liquid metal through the first trench in the protective gas atmosphere includes: nitrogen is introduced into the injection chamber 31, and the cavity is injected with the liquid metal through the first trench by opening the injection structure 32 in a nitrogen atmosphere. The image information of the cavity is collected in the injection process of the liquid metal includes: the light source 34 is turned on in the injection process of the liquid metal, the image information of the cavity is collected by the image collection device 33, the image information is transmitted to a display so that the display displays the image information. The local temperature of the heating platform is adjusted in the injection process according to the image information includes: whether a bubble having a diameter greater than a preset diameter exists is determined according to the image information, and under the condition that the bubble having the diameter greater than the preset diameter exists, a heating temperature of the heating array corresponding to a position of the bubble is adjusted according to the position of the bubble. The heating temperature of the heating array corresponding to a position of the bubble is adjusted according to the position of the bubble includes: an input voltage is determined according to the position of the bubble, an input voltage of the corresponding heating array is adjusted according to the input voltage, and the heating temperature of the heating array is adjusted accordingly.

The method further includes: whether a volume of the liquid metal in the cavity is greater than or equal to a predetermined volume is determined according to the image information; the injection structure is controlled to stop injection under the condition that it is determined that the volume of the liquid metal in the cavity is greater than or equal to the predetermined volume.

Specifically, those skilled in the art may flexibly set a specific numerical value of the predetermined volume according to actual needs, for example, setting the predetermined volume to 90% of a total volume of the cavity. The volume of the liquid metal in the cavity may be determined according to the image information in a following manner: the predetermined volume is converted into a corresponding cavity height, and whether the volume reaches the predetermined volume is determined according to an actual height of the cavity.

Due to irregular and non-uniform arrangement features of a TSV array, when the liquid metal is injected and sealed into the cavity of the TSV interposer, an optimal infiltration path with minimum flow resistance will inevitably appear, resulting in that a large number of nitrogen bubbles are blocked in the cavity and cannot be discharged in time. As a result, in an injecting and sealing process, an input voltage of a part of the heating array of the heating platform is adjusted based on Marangoni effect, a controllable temperature gradient change is formed in the cavity, distribution of super-wettability thermal slip areas of a heterogeneous interface in the cavity is changed in real time, and the infiltration path of the liquid metal in the cavity is optimized.

In a specific embodiment, as shown in FIG. 12, two image collection devices are provided. One of the image collection devices 33 is located at a side, far away from the heating platform 30, of the injection structure 32, is an infrared micro camera, and uses light transmittance of an infrared band in the silicon material of the substrate for collecting the image of the cavity and detecting a filling effect of the liquid metal, a flowing state of the liquid metal in the cavity and a regional temperature change of the liquid metal in real time. The other image collection device 33, a high-speed camera, is located at a side, far away from the light source 34, of the heating platform 30. The injection chamber 31 may be a nitrogen gas glove box made of an acrylic material, and has an external length, width and height of 1200 mm, 800 mm and 700 mm respectively. Glove ports 35 are provided at a left side and a right side of a box body, and a side of the box body is provided with a gas inlet and outlet ball valve 36 for nitrogen change. The heating platform has a length and a width of 120 mm and 150 mm respectively, and three-axis displacement strokes of the heating platform are 60 mm front and back 35 mm left and right, and 80 mm up and down respectively, each of which has accuracy of 0.1 m. The injection structure is a syringe with a needle. The light source is an industrial-grade cold light source with dense LEDs and an adjustable blue tone, such that illumination can be implemented in a horizontal direction.

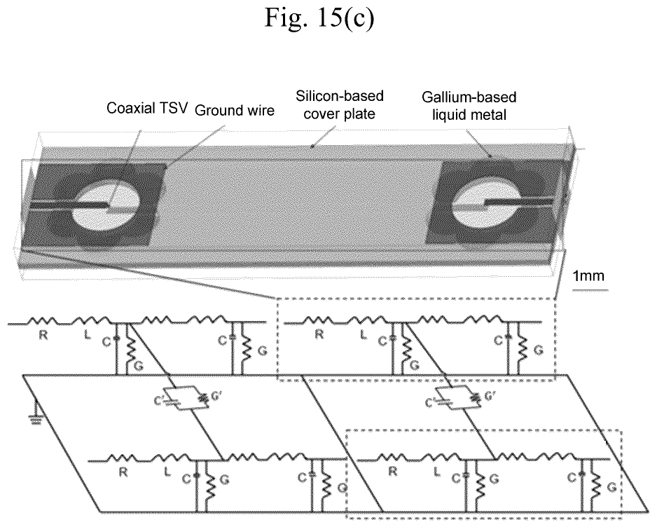

According to some other embodiments, as shown in FIG. 13, the substrate 10 is internally provided with a plurality of cavities 11 arranged at intervals. S202 that the via hole structure that penetrates the substrate is formed at the side of the cavity includes: one via hole structure 13 is formed at the side of each cavity, and the via hole structures and the cavities are arranged alternately. After the first trench 15 is filled with the second structural layer 16, subsequent machining steps, such as cutting and packaging, may be performed to complete final product fabrication. These machining steps may be performed according to specific requirements to obtain fully functional and reliable liquid metal-embedded TSV products. In this product, the thickness of the TSV interposer is 200 μm, an outer wall of the TSV interposer is composed of silicon, and 100 nm thick nano-structured gallium nitride heterogeneous interfaces are formed on an upper surface and a lower surface of the cavity through epitaxy. Except for the gallium nitride heterogeneous interfaces, the cavity has a height of 100 μm, and is filled with liquid gallium-based liquid metal. In the TSV interposer, the via hole structure is in a nested cylindrical shape.

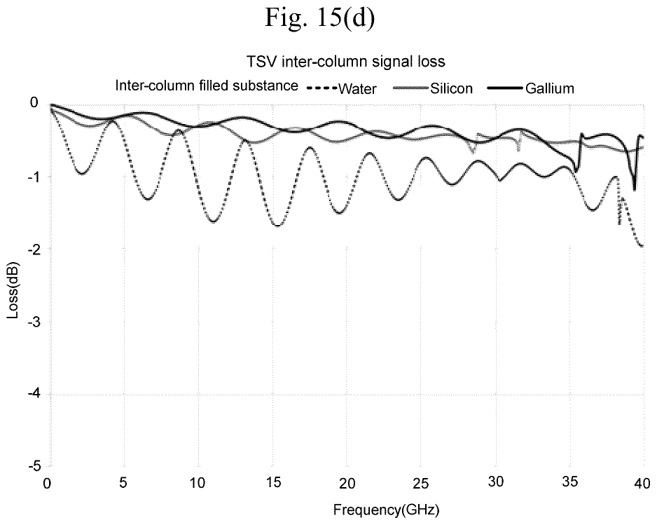

The TSV interposer of the disclosure may be applied to a transceiver. FIG. 14 illustratively shows an explosion diagram of a TSV interposer of a single-band radio frequency transmitter/receiver (T/R) sub-array, and two radio frequency power amplifier (PA) chips are arranged at a top, a bottom of an internal liquid metal flow area is a square with a side length of 12.5 mm, and a cavity height is 100 μm. There are regular hexagonal grounding wires around an internal TSV signal transmission area, and a layout of regular hexagonal grounding wires is conducive to equalization of minimum distances between grounding wires, such that an inductance and a resistance of a circuit are minimized to the greatest extent. This coaxial-like TSV array structure can provide a desirable shielding effect, reduce mutual interference with surrounding signals, and help to guarantee stable signal transmission and reduce interference.

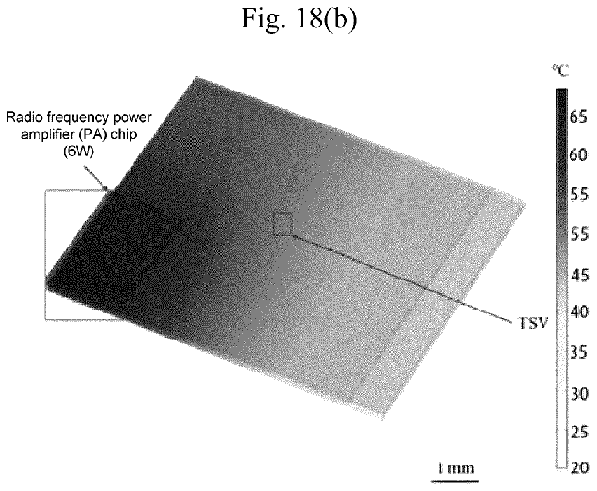

In the disclosure, a heat dissipation model of the TSV interposer may be constructed by combining relevant parameters of the gallium-based liquid metal on the heterogeneous interface, such as dynamic viscosity and slip power, obtained through super-wettability cross-scale thermal slip simulation of the heterogeneous interface of a liquid metal nanostructure, and obtained simulation results are shown in FIG. 18. As shown in FIG. 18(a), under the condition of natural convection with CPU power of 6 W and an ambient temperature of 20° C., a highest temperature of the TSV interposer is 56° C., and is lower than a highest temperature of a standard TSV interposer in the prior art with temperature difference of 36.2° C.

When the TSV interposer of the disclosure is applied to a radio frequency T/R sub-frame, due to a low TSV array density of TSV interposer in the radio frequency T/R sub-array, the gallium-based liquid metal cannot be isolated by the TSV array, and numerous local adaptive thermal reflow paths are formed. As shown in FIG. 18(b), under the natural convection conditions of radio frequency PA chip power of 6 W and an ambient temperature of 20° C., a highest temperature of a liquid metal-embedded TSV interposer of the radio frequency T/R sub-array is 68° C., and is also lower than a highest temperature of a TSV interposer of a standard radio frequency T/R sub-array by 31° C. To sum up, the TSV interposer of the disclosure has excellent temperature uniformity performance, a thermal slip speed of the gallium-based liquid metal can be enhanced through an epitaxial nanostructured gallium nitride layer, and a radial passive heat dissipation capacity of the TSV interposer can be enhanced without affecting a relevant standard process of an existing interposer.

TABLE 1
Simulation parameter setting table of high frequency
signal inter-column loss of a TSV array

| | | Single-band radio |
|---|---|---|
| | Single CPU computation | frequency T/R sub-array |
| Structure | unit parameter | parameter |
| TSV copper column | Column with a diameter | Column with a diameter |
| radius | of 30 μm | of 30 μm |
| TSV SiO₂ layer | 0.5 μm thick | 0.5 μm thick |
| TSV silicon layer | Column with a diameter | Column with a diameter |
| | of 60 μm | of 1.2 mm |
| Copper wire | 5 μm thick and 40 μm | 10 μm thick and 0.2 μm |
| | wide | wide |
| Cover plate of an | 50 μm thick at top and | 50 μm thick at top and |
| interposer | bottom | bottom |
| Cavity | 100 μm high | 100 μm high |
| TSV interval | 90 μm | 10 mm |

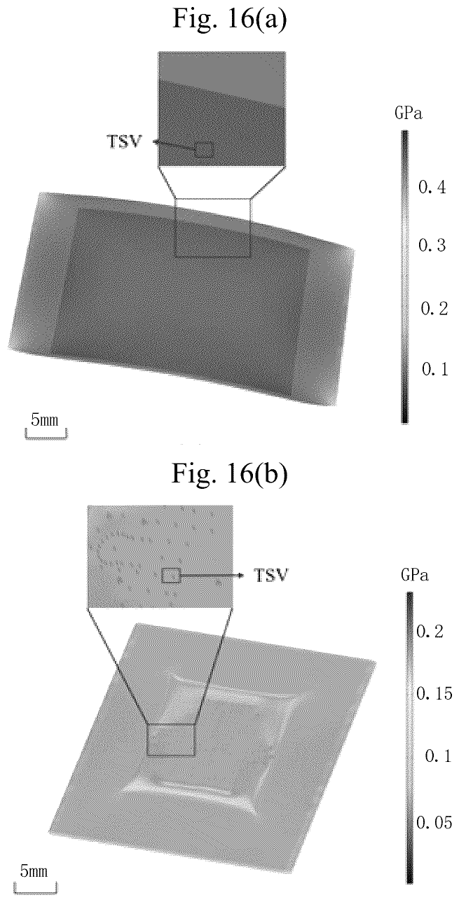

For two typical TSV array structures (a parallel array and a coaxial-like array) in the single CPU computation unit and single-band radio frequency front-end T/R sub-arrays, water, silicon and gallium are used as TSV inter-array filling materials, and simulation and optimization of high-frequency signal inter-column losses are performed separately, as shown in FIGS. 15(a), (b), (c) and (d). The simulation boundary conditions are set as shown in Table 1.

In the model, the cavity is filled with the gallium-based liquid metal. Since a geometric shape of a liquid working medium has little change and has little influence on an electrical signal, the substance in the cavity is regarded as a complete heat dissipation working medium during simulation. It can be seen from simulation results that owing to the desirable signal shielding performance of the gallium-based liquid metal, the high-frequency signal inter-column losses of the two kinds of TSV interposers filled with the gallium-based liquid metal are obviously better than that of an embedded water-cooled interposer and are less than 0.5 dB in the range of 1 GHz-40 GHz, and broad frequency performance of the TSV interposers is also improved compared with that of silicon. Relevant formulas involved in the simulation are as follows:

$$[ \begin{matrix}A & B \\ C & D\end{matrix} ] = [ \begin{matrix}cos h ( θ {h}_{TSV} ) & {Z}_{0} sin h ( θ {h}_{TSV} ) \\ \frac{1}{{Z}_{0}} sin h ( θ {h}_{TSV} ) & cos h ( θ {h}_{TSV} )\end{matrix} ] \qquad ( 1 )$$

Formula (1) is an ABCD parameter matrix (also referred to as transmission line parameters) of the TSV array, and is given by extracting a resistance, an inductance, a capacitance and a conductance (RLCG), and Z₀, θ and h_{TSV} indicate a characteristic impedance, a propagation constant and a TSV height of the C-TSV array respectively. Based on this formula, a return loss (S21) of the structure may be obtained, and is specifically shown in formula (2).

$${S}_{21} = \frac{2}{A + \frac{B}{Z} + CZ + D} \qquad ( 2 )$$

In order to achieve a TSV interposer with high process compatibility, in addition to optimization of heat dissipation and temperature uniformity performance and electrical signal shielding performance, relevant optimization of accumulated stresses under working conditions of the interposer is essential. Under the working conditions of the TSV interposer, stress simulation is performed for the TSV interposer. A stress source is mainly caused by thermal strain caused by temperature change under working conditions according to a specific formula as follows:

$$α = \frac{Δ L}{L \cdot Δ T} \qquad ( 3 )$$

$${ε}_{T} = α ( {T}_{2} - {T}_{1} ) = αΔ T \qquad ( 4 )$$

In the formula, α indicates a thermal expansion coefficient of a material, L indicates an initial length of an object, ΔT indicates change of the length of the object at a certain temperature, and ε_{T} indicates strain of the object at a certain temperature. In the disclosure, the TSV interposer is mainly made from silicon structurally, so the parameter setting is based on a thermal expansion coefficient of silicon. The stress on the object is shown in the following formula:

$$σ = E \times {ε}_{T} \qquad ( 5 )$$

In the formula, σ indicates the stress on the object.

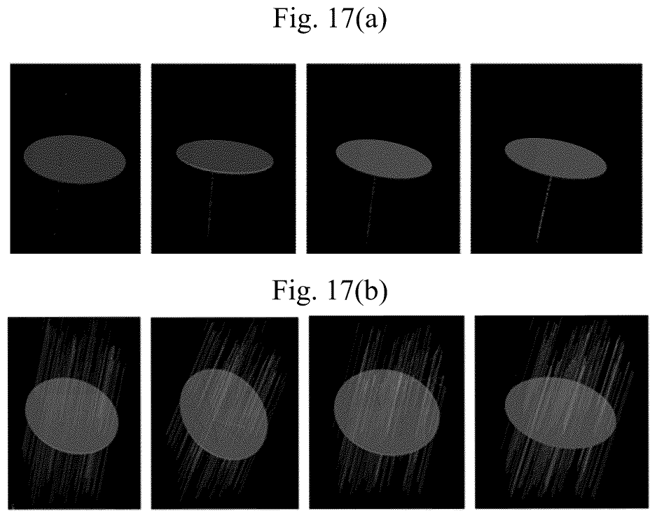

In order to comprehensively verify stress and strain conditions under extreme working conditions of the TSV interposer to be developed in the disclosure, the disclosure sets an external temperature that repeatedly cycling within 250° C.-450° C., and comprehensively simulates accumulated stresses and strains of the TSV interposer of the single CPU computation unit and the TSV interposer of the single-band radio frequency T/R sub-array separately. Final results are shown in FIGS. 16(a) and (b). For the TSV interposer of the single CPU computation unit, a maximum residual stress is 0.49 GPa, and for the TSV interposer of the single-band radio frequency T/R sub-array, a maximum stress is 0.23 GPa, and a maximum compressive stress of silicon (3.5 GPa-4 GPa) is much higher than the above values. Based on this, the TSV interposer of the disclosure can withstand a harsh working environment and has high process compatibility.

In aerospace, main components of cosmic rays are high-energy protons and some γ rays. The high-energy protons are incident into a semiconductor device, and an interaction mechanism between the incident protons and semiconductor materials is bremsstrahlung, and is interaction between the protons and Coulomb field of a nucleus when protons are close to the nucleus. The protons deflect in a movement direction and slow down sharply, and energy is converted into radiation according to a formula as follows:

$$B = \frac{{e}_{r}}{c} \times E = \frac{{a}^{2} {q}^{2}}{4 π r {ε}_{0} {c}^{3}} \frac{{e}_{r} \times a}{{( 1 - \frac{{ve}_{r}}{c} )}^{3}} \qquad ( 6 )$$

$$S = E \times H = \frac{{a}^{2} {q}^{2}}{16 {r}^{2} {c}^{3} {π}^{2} {ε}_{0}} \frac{{sin}^{2} θ}{{( 1 - \frac{V}{C} cos θ )}^{6}} {e}^{r} \qquad ( 7 )$$

In the formula, E indicates an electric field intensity vector, q indicates an electric quantity of a charged particle, r indicates a distance between an observation point and the charged particle, c indicates a speed of light in vacuum, ε₀ indicates a vacuum dielectric constant, a indicates an acceleration vector, εᵣ indicates a unit radial vector pointing to space from a center of the charged particle, v indicates a charged particle velocity, b indicates a magnetic induction intensity vector, and S indicates an energy flow density vector, and θ indicates an included angle between an advancing direction of the particle and εᵣ.

An interaction mechanism between the γ rays and the semiconductor materials is mainly Compton effect. γ photons elastically collide with electrons (can be regarded as free electrons) in an outer layer of an atom elastically. γ-photons merely transfer a part of energy to the electrons in the outer layer of the atom, such that the electrons can be ejected from the atom after getting rid of bondage by the nucleus. A movement direction of the photons is changed. Emitted electrons are referred to as Compton electrons and can continue to interact with a medium. A Compton effect formula is as follows:

$$Δλ = λ - {λ}_{0} = \frac{h}{mc} {sin}^{2} ( \frac{φ}{2} ) \qquad ( 8 )$$

In the formula, Δλ indicates a difference between an incident wavelength λ₀ and a scattering wavelength λ, h indicates Planck constant, c indicates a speed of light, m indicates rest mass of electrons and φ indicates a scattering angle.

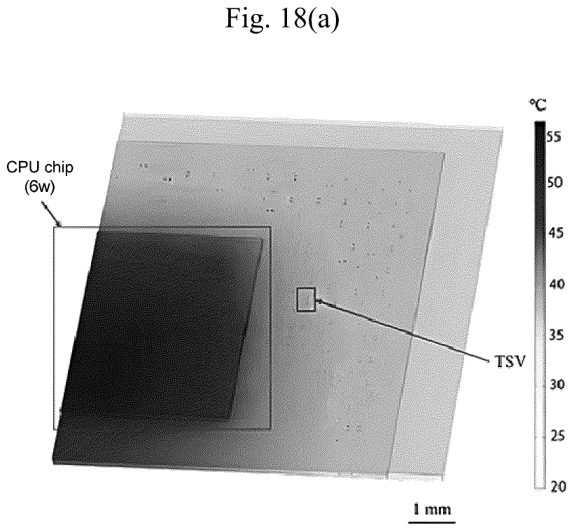

In addition to silver addition for adjustment of heat dissipation and electromagnetic shielding, a certain proportion of lead may be added into a gallium-based alloy. The radiation resistance of the TSV interposer can be further improved through uniform distribution of large-mass atoms such as silver and lead in the cavity. Single particle simulation and total dose simulation are performed on a 200 μm thick silicon substrate, a 200 μm thick embedded 100 μm gallium silicon substrate, a 200 μm thick embedded 100 μm Ga₆₅In_{20.5}Sn_{9.5}Pb₅ silicon substrate, and a 3.8 mm molybdenum-copper cover plate separately, as shown in FIGS. 17(a) and (b) and Tables 2 and 3. In the single particle simulation, under irradiation of a single proton with energy of 6 MeV, the proton can penetrate the 200 μm silicon substrate, while 100 μm metal gallium, 100 μm gallium-based alloy and the 3.8 mm molybdenum-copper cover plate block the proton and prevent the proton from causing radiation damage to internal devices. Under irradiation of 10 MeV protons, the 3.8 mm molybdenum-copper cover plate blocked the protons, and although the 100 μm metal gallium and the 100 μm gallium-based alloy can not completely block the protons, the metal gallium and the gallium-based alloy effectively protect materials behind and reduce energy deposition of the 50 μm thick silicon layer on a back of the TSV interposer. In the total dose simulation, 100 gamma particles with energy of 6 MeV are arranged for irradiation, and a simulation result shows that energy deposition is generated in the embedded gallium and gallium-based alloys, accompanied by generation of negative electrons and protons. As a result, the liquid metal-embedded TSV interposer in this design solution can provide an enhanced radiation protection effect for an internal structure.

TABLE 2
Single particle simulation energy deposition of high-energy protons

| Single particle simulation of | | | Single particle simulation of | | |
|---|---|---|---|---|---|
| 6 MeV protons | | | 10 MeV protons | | |
| 200 μm silicon substrate | | | 200 μm silicon substrate | | |
| Front 50 μm silicon | 728.6 | keV | Front 50 μm silicon | 415.9 | keV |
| energy deposition | | | energy deposition | | |
| Central 100 μm | 1.911 | MeV | Central 100 μm | 940.3 | keV |
| silicon energy | | | silicon energy | | |
| deposition | | | deposition | | |
| Back 50 μm silicon | 1.772 | MeV | Back 50 μm silicon | 654.7 | keV |
| energy deposition | | | energy deposition | | |
| Embedded 100 μm gallium | | | Embedded 100 μm gallium | | |
| Front 50 μm silicon | 728.6 | keV | Front 50 μm silicon | 415.9 | keV |
| energy deposition | | | energy deposition | | |
| Gallium layer energy | 4.078 | MeV | Gallium layer energy | 1.863 | MeV |
| deposition | | | deposition | | |
| Back 50 μm silicon | 0 | eV | Back 50 μm silicon | 567.7 | keV |
| energy deposition | | | energy deposition | | |
| Embedded 100 μm Ga₆₅In_{20.5}Sn_{9.5}Pb₅ | | | Embedded 100 μm Ga₆₅In_{20.5}Sn_{9.5}Pb₅ | | |
| Front 50 μm silicon | 728.6 | keV | Front 50 μm silicon | 415.9 | keV |
| energy deposition | | | energy deposition | | |
| Alloy layer energy | 4.062 | MeV | Alloy layer energy | 1.96 | MeV |
| deposition | | | deposition | | |
| Back 50 μm silicon | 0 | eV | Back 50 μm silicon | 574.6.2 | keV |
| energy deposition | | | energy deposition | | |
| 3.8 mm molybdenum-copper cover plate | | | 3.8 mm molybdenum-copper cover plate | | |
| Molybdenum-copper | 4.824 | MeV | Molybdenum-copper | 9.203 | MeV |
| energy deposition | | | energy deposition | | |
| Cover plate back | 0 | eV | Cover plate back | 0 | eV |
| side energy | | | side energy | | |
| deposition | | | deposition | | |

TABLE 3
Total dose simulation energy deposition of γ particles
Total dose simulation of gamma particles
3.8 mm molybdenum-copper cover plate

| | |
|---|---|
| Energy deposition | 1118.96 keV |

200 μm silicon substrate

| | |
|---|---|
| Energy deposition | 422.35 keV |

Embedded 100 μm gallium

| | |
|---|---|
| Energy deposition | 281.22 keV |

Embedded 100 μm Ga₆₅In_{20.5}Sn_{9.5}Pb₅

| | |
|---|---|
| Energy deposition | 249.61 keV |

According to still another aspect of the disclosure, a three-dimensional chip is provided. The three-dimensional chip includes: any of the TSV interposer described above, or the TSV interposer obtained by any of the method for manufacturing the TSV interposer described above. The three-dimensional chip includes any said of the TSV interposer, or the TSV interposer obtained by any of the method described above. In the TSV interposer, athe via hole structure penetrates the substrate, the cavity is located inside the substrate and at the side of the via hole structure, the first structural layer covers the part of the inner wall of the cavity, and the liquid metal is located in the cavity. According to the disclosure, the liquid metal is formed in the cavity inside the TSV interposer, such that heat dissipation performance of the TSV interposer can be improved by utilizing a high thermal conductivity of the liquid metal, and the problem of poor heat dissipation capacity of the TSV interposer in the prior art is alleviated. Moreover, a fully connected cavity of the via hole structure which is located at the side of the cavity naturally forms a kind of planar heat pipe micro-needle fin wick structure, and provides a favorable space environment for adaptive thermal reflux of the liquid metal. In addition, the material types of the first structural layer and the substrate are different, and the first structural layer and the liquid metal have the same material element. In this way, the first structural layer plays a heterogeneous transition role between the substrate and the liquid metal, the liquid metal has desirable fluidity in the cavity, and an overall cooling effect on the TSV interposer is further guaranteed to be desirable.

It should also be noted that the terms “comprise” and “include” or their other variants intend to cover non-exclusive inclusion, such that a process, a method, a product or a device including a series of elements not only includes those elements, but includes other elements not listed clearly, or further includes elements inherent to the process, method, product or device. In the case of no more limitation, an element limited by the phrases “comprise a . . . ” and “include a . . . ” does not exclude another same element existing in a process, method, product or device including the element.

The above embodiments are merely preferred embodiments of the disclosure and are not intended to limit the disclosure, and for a person of ordinary skill in the art, various modifications and changes can be made to the disclosure. Any modification, equivalent substitution and improvement, etc. made within the spirit and principles of the disclosure shall fall within the scope of protection of the disclosure.

1. A through-silicon via (TSV) interposer, comprising:
a substrate, wherein an interior of the substrate is provided with a cavity and a first structural layer covering a part of an inner wall of the cavity, and a material type of the first structural layer is different from a material type of the substrate;
a via hole structure that penetrates the substrate and is located at a side of the cavity; and
liquid metal located in the cavity, wherein the liquid metal and the first structural layer comprise a same material element.

2. The TSV interposer according to claim 1, wherein the TSV interposer further comprises:
a first trench that penetrates a part of a surface of the substrate and a part of a surface of the first structural layer and is in communication with the cavity; and
a second structural layer located in the first trench.

3. The TSV interposer according to claim 1, wherein the substrate comprises:
a first sub-substrate;
a second trench extending into the first sub-substrate from a surface of the first sub-substrate;
a first structural sub-layer located at a bottom of the second trench;
a second sub-substrate, wherein a surface of the second sub-substrate is bonded to the surface of the first sub-substrate;
a third trench extending into the second sub-substrate from the surface of the second sub-substrate, wherein the second trench and the third trench correspond to each other, so as to constitute the cavity; and
a second structural sub-layer located at a bottom of the third trench, wherein the first structural sub-layer and the second structural sub-layer constitute the first structural layer.

4. The TSV interposer according to claim 1, wherein the via hole structure comprises:
a via hole that penetrates the substrate and is located at the side of the cavity;
an insulation layer covering a hole wall of the via hole;
a barrier layer located on a surface, far away from the hole wall of the via hole, of the insulation layer; and
a conductive layer located on a surface, far away from the insulation layer, of the barrier layer.

5. The TSV interposer according to claim 1, wherein the TSV interposer further comprises:
a first metal connection structure located on a surface of the substrate, wherein the first metal connection structure is in contact with the via hole structure; and
a second metal connection structure located on a surface, far away from the substrate, of the first metal connection structure.

6. The TSV interposer according to claim 1, wherein a material of the first structural layer comprises a gallium-containing compound, and the liquid metal comprises gallium.

7. The TSV interposer according to any one of claims 1-5, wherein the liquid metal further comprises at least one of silver, indium, tin, graphene, diamond nanoparticles and nitrogen boride.

8. A method for manufacturing a TSV interposer, wherein the TSV interposer comprises:
a substrate, wherein an interior of the substrate is provided with a cavity and a first structural layer covering a part of an inner wall of the cavity, and a material type of the first structural layer is different from a material type of the substrate;
a via hole structure that penetrates the substrate and is located at a side of the cavity; and
liquid metal located in the cavity, wherein the liquid metal and the first structural layer comprise a same material element,
the method comprising:
providing the substrate, wherein the interior of the substrate is provided with the cavity and the first structural layer covering the part of the inner wall of the cavity, and the material type of the first structural layer is different from the material type of the substrate;
forming the via hole structure that penetrates the substrate at the side of the cavity; and
injecting the cavity with the liquid metal to obtain the TSV interposer, wherein the liquid metal and the first structural layer comprise the same material element.

9. The method according to claim 8, wherein injecting the cavity with the liquid metal to obtain the TSV interposer comprises:
forming a first trench that sequentially penetrates the substrate and the first structural layer into the cavity;
injecting the cavity with the liquid metal through the first trench; and
filling the first trench with a second structural layer, and curing the second structural layer.

10. The method according to claim 9, wherein injecting the cavity with the liquid metal through the first trench comprises:
placing the substrate that is provided with the first trench on a heating platform, wherein temperature of the heating platform is higher than or equal to a melting point of the liquid metal;
injecting the cavity with the liquid metal through the first trench in a protective gas atmosphere;
collecting image information of the cavity in an injection process of the liquid metal; and
adjusting local temperature of the heating platform in the injection process according to the image information, and removing partial bubbles from the liquid metal.

11. The method according to claim 10, wherein the heating platform is located in an injection chamber; the heating platform comprises a plurality of heating arrays, and the injection chamber further comprises an injection structure filled with the liquid metal, an image collection device and a light source; and the injection structure is located above the heating platform, the light source is located at a side of the heating platform, and the image collection device is located at a side of at least one of the following: a side, far away from the heating platform, of the injection structure, and a side, far away from the light source, of the heating platform;
injecting the cavity with the liquid metal through the first trench in the protective gas atmosphere comprises: introducing nitrogen into the injection chamber, and injecting the cavity with the liquid metal through the first trench by opening the injection structure in a nitrogen atmosphere;
collecting the image information of the cavity in the injection process of the liquid metal comprises: turning on the light source in the injection process of the liquid metal, collecting the image information of the cavity by the image collection device, transmitting the image information to a display so that the display displays the image information; and
adjusting the local temperature of the heating platform in the injection process according to the image information comprises: determining whether a bubble having a diameter greater than a preset diameter exists according to the image information, and under the condition that the bubble having the diameter greater than the preset diameter exists, adjusting a heating temperature of the heating array corresponding to a position of the bubble according to the position of the bubble.

12. The method according to claim 8, wherein providing the substrate comprises:
providing a first sub-substrate, removing a part of the first sub-substrate, and forming a second trench that extends into the first sub-substrate from a surface of the first sub-substrate;
forming a first structural sub-layer at a bottom of the second trench;
providing a second sub-substrate, removing a part of the second sub-substrate, and forming a third trench that extends into the second sub-substrate from a surface of the second sub-substrate;
forming a second structural sub-layer at a bottom of the third trench, wherein the first structural sub-layer and the second structural sub-layer constitute the first structural layer; and
bonding the first sub-substrate that is provided with the first structural sub-layer to the second sub-substrate that is provided with the second structural sub-layer by taking the surface of the first sub-substrate and the surface of the second sub-substrate as bonding interfaces, and obtaining the substrate, wherein the second trench and the third trench constitute the cavity.

13. The method according to claim 8, wherein forming the via hole structure that penetrates the substrate at the side of the cavity comprises:
removing a part of the substrate, and forming a fourth initial trench that extends into the substrate from a first surface of the substrate;
sequentially forming an insulation layer, a barrier layer and a conductive layer on a side wall of the fourth initial trench, and obtaining a fourth trench; and
polishing the substrate along a second surface of the substrate until the fourth trench is cut through so as to obtain the via hole structure, wherein the first surface and the second surface are two opposite surfaces of the substrate.

14. The method according to claim 13, wherein after obtaining the via hole structure, the method further comprises:
performing redistributing on the first surface and the second surface to obtain a first metal connection structure in contact with the via hole structure; and
forming a second metal connection structure on a surface, far away from the substrate, of the first metal connection structure.

15. A three-dimensional chip, comprising: a TSV interposer or a TSV interposer obtained by a method for manufacturing a TSV interposer, wherein the TSV interposer comprises:
a substrate, wherein an interior of the substrate is provided with a cavity and a first structural layer covering a part of an inner wall of the cavity, and a material type of the first structural layer is different from a material type of the substrate;
a via hole structure that penetrates the substrate and is located at a side of the cavity; and
liquid metal located in the cavity, wherein the liquid metal and the first structural layer comprise a same material element,
the method comprises:
providing the substrate, wherein the interior of the substrate is provided with the cavity and the first structural layer covering the part of the inner wall of the cavity, and the material type of the first structural layer is different from the material type of the substrate;
forming the via hole structure that penetrates the substrate at the side of the cavity; and
injecting the cavity with liquid metal to obtain the TSV interposer, wherein the liquid metal and the first structural layer comprise the same material element.

16. The TSV interposer according to claim 2, wherein a material of the first structural layer comprises a gallium-containing compound, and the liquid metal comprises gallium.

17. The TSV interposer according to claim 3, wherein a material of the first structural layer comprises a gallium-containing compound, and the liquid metal comprises gallium.

18. The TSV interposer according to claim 4, wherein a material of the first structural layer comprises a gallium-containing compound, and the liquid metal comprises gallium.

19. The TSV interposer according to claim 5, wherein a material of the first structural layer comprises a gallium-containing compound, and the liquid metal comprises gallium.

20. The TSV interposer according to claim 2, wherein the liquid metal further comprises at least one of silver, indium, tin, graphene, diamond nanoparticles and nitrogen boride.
